(19) United States
(12) Patent Application Publication
(10) Pub. No.: US 2024/0312870 A1
(43) Pub. Date: Sep. 19, 2024

(54) HEAT RADIATING MEMBER AND SEMICONDUCTOR MODULE

(71) Applicant: NIDEC CORPORATION, Kyoto (JP)

(72) Inventors: Kazuhiro NISHIKAWA, Kyoto (JP); Yuta HORI, Kyoto (JP)

(21) Appl. No.: 18/396,710

(22) Filed: Dec. 27, 2023

(30) Foreign Application Priority Data
Mar. 17, 2023 (JP) 2023-042640

(51) Int. Cl. H01L 23/473

(52) U.S. Cl. CPC H01L 23/473

(57) ABSTRACT

At least one of a plurality of fins includes a plurality of fin regions in a first direction, the plurality of fin regions facing a plurality of semiconductor elements in a third direction, the plurality of the semiconductor elements being disposed in the first direction, and the plurality of fin regions includes two or more fin regions each of which includes the side wall part provided with a spoiler. The spoiler is equal in number between the two or more fin regions, and flow path resistance due to structure of the spoiler in each of the fin regions increases from an upstream side toward a downstream side of the corresponding one of the fin regions through which a refrigerant flows.

### CROSS-REFERENCE TO RELATED APPLICATIONS

The present invention claims priority under 35 U.S.C. § 119 to Japanese Patent Application No. 2023-042640 filed on Mar. 17, 2023, the entire content of which is incorporated herein by reference.

### FIELD OF THE INVENTION

The present disclosure relates to a heat radiating member.

### BACKGROUND

Heat radiating members are conventionally used for cooling heating elements. The heat radiating members each includes a base part and a plurality of fins. The plurality of fins protrudes from the base part. When a refrigerant such as water flows between adjacent fins in the plurality of fins, heat of the heating element moves to the refrigerant.

In recent years, a technique for cooling a semiconductor element such as an insulated gate bipolar transistor (IGBT) using a heat radiating member has become important in in-vehicle applications and the like. The conventional heat radiating members have a problem that a plurality of semiconductor elements disposed in a direction in which a refrigerant flows causes the refrigerant to be increased in temperature toward a downstream side due to heat transfer, thereby causing a temperature difference between the semiconductor elements.

### SUMMARY

An exemplary heat radiating member of the present disclosure cools an insulating circuit board equipped with a semiconductor element, and includes: a base part in a plate shape that extends in a first direction along a refrigerant flow direction and in a second direction orthogonal to the first direction with a thickness in a third direction orthogonal to the first direction and the second direction, and includes the insulating circuit board disposed on a first side in the third direction; and a plurality of fins that protrudes from the base part toward a second side in the third direction and includes a side wall part in a plate shape extending in the first direction and the third direction and having a thickness direction in the second direction, the plurality of fins being disposed in the second direction. At least one of the plurality of fins includes a plurality of fin regions in the first direction, the plurality of fin regions facing a plurality of the semiconductor elements in the third direction, the plurality of the semiconductor elements being disposed in the first direction. The plurality of fin regions includes two or more fin regions each of which includes the side wall part provided with a spoiler. The spoiler is equal in number between the two or more fin regions, and flow path resistance due to structure of the spoiler in each of the fin regions increases from an upstream side toward a downstream side of the corresponding one of the fin regions through which the refrigerant flows.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a heat radiating member according to an exemplary embodiment of the present disclosure;

FIG. 2 is a side view of a heat radiating member according to an exemplary embodiment of the present disclosure when an intermediate part in a second direction is viewed from the second side in the second direction to a first side in the second direction;

FIG. 3 is a plan view of a heat radiating member according to an exemplary embodiment of the present disclosure as viewed from the second side in a third direction to a first side in the third direction;

FIG. 4 is a perspective view illustrating an example of a single spoiler;

FIG. 5 is a perspective view illustrating an example of a double spoiler;

FIG. 6 is a diagram for illustrating length adjustment of a spoiler;

FIG. 7 is a diagram for illustrating adjustment of the amount of protrusion of a spoiler; and

FIG. 8 is a diagram for illustrating angle adjustment of a spoiler.

### DETAILED DESCRIPTION

Hereinafter, an exemplary embodiment of the present disclosure will be described with reference to the drawings.

The drawings each indicate a first direction as an X direction in which X1 indicates a first side in the first direction and X2 indicates a second side in the first direction. The first direction is along a direction F in which a refrigerant W flows, and F1 indicates a downstream side and F2 indicates an upstream side. The first direction is orthogonal to a second direction as a Y direction in which Y1 indicates a first side in the second direction, and Y2 indicates a second side in the second direction. The first direction and the second direction are orthogonal to a third direction as a Z direction in which Z1 indicates a first side in the third direction, and Z2 indicates a second side in the third direction. The above-described orthogonal also includes intersection at an angle slightly shifted from 90 degrees. Each of the above-described directions does not limit a direction when a heat radiating member is incorporated in various devices.

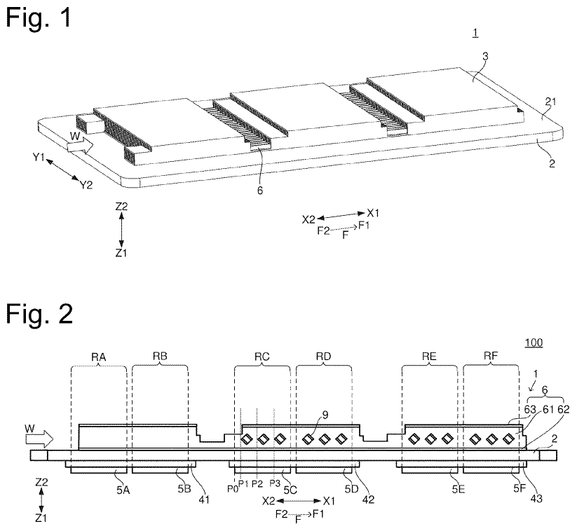

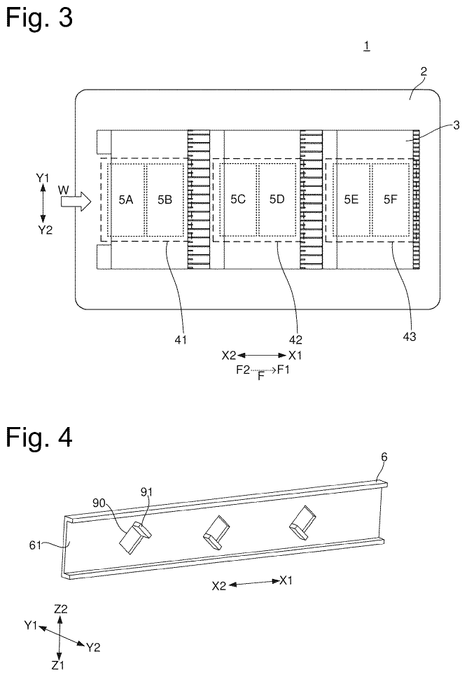

FIG. 1 is a perspective view of a heat radiating member 1 according to an exemplary embodiment of the present disclosure. FIG. 2 is a side view of the heat radiating member 1 according to the exemplary embodiment of the present disclosure when an intermediate part in the second direction is viewed from the second side in the second direction to the first side in the second direction. FIG. 3 is a plan view of the heat radiating member 1 as viewed from the second side in the third direction to the first side in the third direction.

FIGS. 2 and 3 each illustrate insulating circuit boards 41 to 43 disposed on the first side in the third direction of the heat radiating member 1 and semiconductor elements 5A to 5F (referred to below as 5A and the like). The heat radiating member 1, the insulating circuit boards 41 to 43, and the semiconductor elements 5A and the like constitute a semiconductor module 100.

The heat radiating member 1 can be installed in a liquid cooling jacket (not illustrated), and includes a base part 2 and a heat radiating fin part 3.

The base part 2 has a plate shape that extends in the first direction and the second direction and has a thickness in the third direction. The base part 2 is made of a metal having high thermal conductivity, such as a copper alloy.

The heat radiating fin part 3 is configured as a so-called stacked fin by disposing a plurality of fins (fin plates) 6 in the second direction. The fins 6 are each formed of a metal plate extending in the first direction, and formed of a copper plate, for example. The heat radiating fin part 3 is fixed to a surface 21 of the base part 2 on the second side in the third direction by brazing, for example.

As illustrated in FIG. 2, each of the fins 6 includes a side wall part 61 extending in the first direction, a bottom plate part 62 extending toward the second side in the second direction at an end of the side wall part 61 on the first side in the third direction, and a top plate part 63 extending toward the second side in the second direction at an end the side wall part 61 on the second side in the third direction. That is, the heat radiating member 1 includes the side wall part 61 in a flat plate shape protruding from the base part 2 to the second side in the third direction and extending in the first direction and the third direction with a thickness direction in the second direction, and the plurality of fins 6 disposed in the second direction. The top plate part 63 is provided by bending a tip of the side wall part 61. However, the top plate part 63 may be provided by attaching a plate-like member to the tip of the side wall part 61.

The refrigerant W flows into the heat radiating fin part 3 from the second side (upstream side) in the first direction to flow through a flow path channel formed between the fins 6 adjacent in the second direction toward the first side (downstream side) in the first direction, and is discharged from the heat radiating fin part 3 toward the first side in the first direction.

The semiconductor elements 5A and the like are heating elements to be cooled by the heat radiating member 1. The semiconductor elements 5A and the like are provided in an inverter provided in a traction motor for driving wheels of a vehicle, for example. The semiconductor elements 5A and the like are each a transistor such as an IGBT.

The insulating circuit boards 41 to 43 are bonded to the base part 2 on the first side in the third direction. The bonding can be performed using various methods capable of fixing the insulating circuit board, such as soldering, welding, welding, and screwing. The insulating circuit boards 41, 42, and 43 are disposed in this order from the second side in the first direction toward the first side in the first direction.

The semiconductor elements 5A and 5B are disposed on the insulating circuit board 41 on the first side in the third direction. The semiconductor element 5B is disposed on the first side in the first direction from the semiconductor element 5A. The semiconductor elements 5C and 5D are disposed on the insulating circuit board 42 on the first side in the third direction. The semiconductor element 5D is disposed on the first side in the first direction from the semiconductor element 5C. The semiconductor elements 5E and 5F are disposed on the insulating circuit board 43 on the first side in the third direction. The semiconductor element 5F is disposed on the first side in the first direction from the semiconductor element 5E.

The insulating circuit board and the semiconductor elements are not limited to the layout described above. The insulating circuit board is not limited in plural number as described above, and may be single. The number of semiconductor elements is not limited to six as described above, and may be a plural number other than six. The semiconductor elements are not limited in one type as described above, and may be in two or more types.

The semiconductor elements 5A and the like generate heat that is transferred to the fins 6 through the insulating circuit boards 41 to 43 and the base part 2, and that moves to the refrigerant W to cool the semiconductor elements 5A and the like. That is, the heat radiating member 1 is for cooling the insulating circuit boards 41 to 43 equipped with the semiconductor elements 5A and the like.

As illustrated in FIG. 2, the side wall part 61 of the fin 6 includes a spoiler 9 in the present embodiment. As described later, the spoiler 9 has two types of a single spoiler and a double spoiler. FIG. 2 illustrates an example in which only a double spoiler is formed as the spoiler 9 on the fin 6. The single spoiler corresponds to one spoiler 9, and the double spoiler corresponds to two spoilers 9.

FIG. 4 is a perspective view illustrating an example of a single spoiler 91. The single spoiler 91 is provided against an opening 90. The opening 90 passes through the side wall part 61 in the second direction. The single spoiler 91 protrudes in the second direction from a first side of the opening 90 in a rectangular shape. The single spoiler 91 is inclined to the first side in the third direction and the first side in the first direction. The single spoiler 91 is provided from a first side of the opening 90 on the first side in the third direction or on the second side in the third direction.

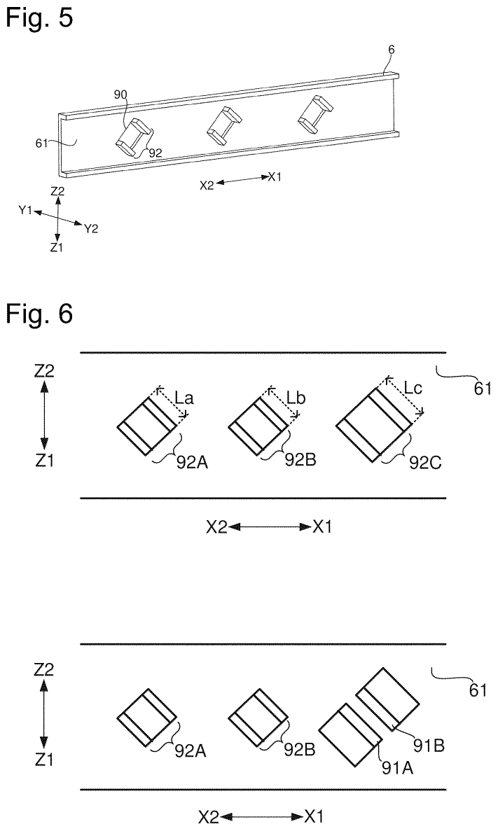

FIG. 5 is a perspective view illustrating an example of a double spoiler 92. The double spoiler 92 is provided against the opening 90. The double spoiler 92 protrudes in the second direction from two opposing sides of the opening 90 in a rectangular shape. The double spoiler 92 is inclined toward the first side in the third direction and the first side in the first direction.

The single spoiler 91 or the double spoiler 92 as described above face in a direction in which the refrigerant W flows, so that a turbulent flow is likely to be generated and a large flow path resistance is likely to be set, thereby improving cooling performance.

As illustrated in FIG. 2, the fin 6 includes a fin region RA facing the semiconductor element 5A in the third direction, a fin region RB facing the semiconductor element 5B in the third direction, a fin region RC facing the semiconductor element 5C in the third direction, a fin region RD facing the semiconductor element 5D in the third direction, a fin region RE facing the semiconductor element 5E in the third direction, and a fin region RF facing the semiconductor element 5F in the third direction. That is, at least one fin 6 includes a plurality of the fin regions RA to RF in the first direction, the plurality of the fin regions RA to RF facing a plurality of the semiconductor elements 5A and the like in the third direction, the plurality of the semiconductor elements 5A and the like being disposed in the first direction.

As illustrated in FIG. 2, the spoiler 9 is provided in each of the fin regions RC, RD, RE, and RF. The fin regions RA and RB include no spoiler 9. In this manner, the spoiler 9 may not necessarily be provided in all the fin regions. That is, the plurality of fin regions RA to RF includes two or more fin regions RC to RF each of which includes the side wall part 61 provided with the spoiler 9.

FIG. 2 illustrates the fin regions RC to RF each of which includes three double spoilers 92, and thus the number of spoilers 9 is six according to the following expression: 2×3=6. That is, the number of spoilers 9 is equal between two or more fin regions RC to RF. FIG. 2 is merely an example, and for example, only the single spoiler 91 may be provided in each of the fin regions RC to RF, or for example, the single spoiler 91 and the double spoiler 92 may be mixed in at least one of the fin regions RC to RF. That is, the number of spoilers may be equal between two or more fin regions according to the following expression: 1×the number of single spoilers+2×the number of double spoilers=the number of spoilers.

As illustrated in FIG. 2, each of the fin regions RC to RF has positions P1, P2, and P3 at each of which the spoiler 9 is formed, and each of which has a relative relationship with respect to a position P0 of an end of the corresponding one of the semiconductor elements 5C to 5F on the second side in the first direction, the relative relationship being identical in each of the fin regions RC to RF.

Flow path resistance in each fin region is adjusted in the present embodiment by not only placement of the spoilers as described above, but also structure of the spoilers. Specifically, the fin regions RC to RF have flow path resistances FRC to FRF, respectively, to satisfy the following relationship: FRC<FRD<FRE<FRF. That is, the flow path resistance is increased toward the downstream side. Besides the above, examples of the relationship may include FRC=FRD=FRE<FRF, FRC=FRD<FRE=FRF, FRC<FRD=FRE=FRF, FRC<FRD=FRE=FRF, and FRC<FRD=FRE<FRF. That is, the flow path resistances in the middle of the direction toward the downstream side may be equal between the fin regions adjacent to each other in the first direction. The structure of the spoilers for adjusting the flow path resistance will be described later.

That is, the flow path resistance due to the structure of the spoilers 9 in the fin regions RC to RF increases as the refrigerant W flows from the fin region RC on the upstream side toward the fin region RF on the downstream side.

The spoilers can easily form a turbulent flow as described above, so that it is conceivable that the number of spoilers is increased on the downstream side to improve cooling performance on the downstream side where the refrigerant W tends to increase in temperature, and the cooling performance of the plurality of semiconductor elements disposed in the first direction is equalized. Unfortunately, the number of spoilers is an integer value, so that a degree of turbulent flow formation cannot be finely adjusted. Additionally, even when the number of spoilers is increased by simply narrowing an interval between the spoilers, the cooling performance may not be improved accordingly under conditions where the refrigerant reaches the spoiler at the subsequent stage while a turbulent flow is generated by the spoiler at the preceding stage. This is because the interval between the spoilers is strongly related to a turbulent flow generation situation. The spoilers are also required to be disposed in a region facing the semiconductor element in the third direction, so that the number of spoilers that can be disposed is limited.

Thus, the present embodiment causes the flow path resistance (the degree of turbulent flow formation) to be adjusted by the structure of the spoilers 9 while equalizing the number of spoilers 9 in each of the two or more fin regions of the fin regions RC to RF, so that cooling performance of the plurality of semiconductor elements 5C to 5F disposed in the first direction can be finely adjusted to facilitate equalization of the cooling performance.

Satisfying the relationship: FRC<FRD<FRE<FRF, for the flow path resistance as described above is, in other words, that each of sets (RC, RD) (RD, RE) (RE, RF) of the fin regions adjacent to each other in the first direction has the flow path resistance that increases from the fin region on the upstream side toward the fin region on the downstream side.

Then, setting the relationship: FRC=FRD=FRE<FRF, for example, for the flow path resistance, as described above is, in other words, that at least one of the sets of the fin regions adjacent to each other in the first direction has the flow path resistance that is equal between the fin regions adjacent to each other.

Next, a structure (design parameter) of the spoiler 9 for adjusting the flow path resistance will be described.

FIG. 6 includes an upper diagram illustrating a specific structure example of the double spoiler 92 when three double spoilers 92 are provided in one fin region as illustrated in FIG. 2. The upper diagram of FIG. 6 illustrates double spoilers 92A, 92B, and 92C that are provided in one fin region. That is, the number of spoilers 9 is six according to the following expression: 2×3=6. The upper diagram of FIG. 6 then illustrates the double spoiler 92C on the most downstream side (the first side in the first direction) having a length Lc extending in the first direction and the third direction that is set longer than lengths La and Lb of the double spoilers 92A and 92B on the upstream side, the lengths La and Lb extending in the first direction and the third direction (Lc>La=Lb).

In this manner, the flow path resistance is adjusted by the length of the spoiler 9 extending in the first direction and the third direction. Increasing the length of the spoiler 9 increases the degree of turbulent flow formation and increases the flow path resistance. Adjusting the length of the spoiler 9 facilitates fine adjustment of the cooling performance.

Then, one fin region includes the spoilers 9 that may have lengths extending in the first direction and the third direction, lengths being equal in all the spoilers 9. FIG. 6 also includes a lower diagram illustrating an example in which two double spoilers 92A and 92B are provided on the upstream side, and two single spoilers 91A and 91B are provided on the downstream side. Even this structure has the number of spoilers that is nine according to the following expression: 9=2×2+1×2=6, and has an effect equivalent to that in the upper diagram of FIG. 6. The lower diagram of FIG. 6 illustrates the single spoilers 91A and 91B each having a length extending in the first direction and the third direction, the length being set longer than lengths of the double spoilers 92A and 92B extending in the first direction and the third direction.

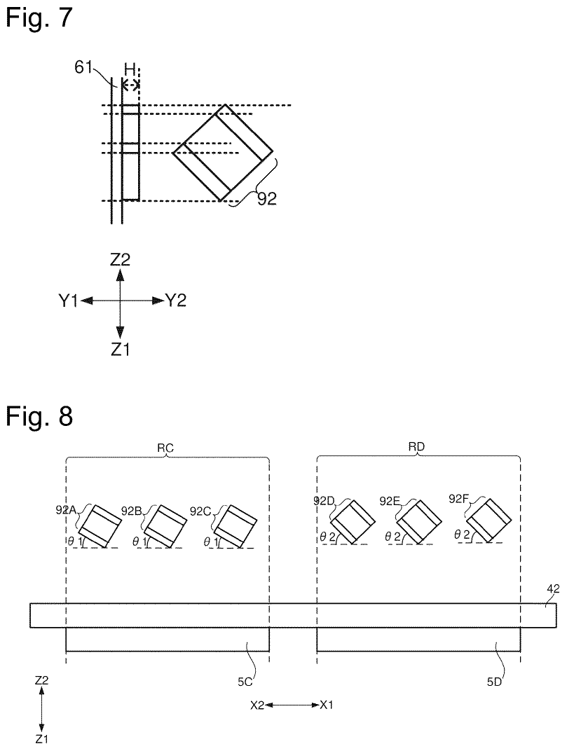

FIG. 7 illustrates the double spoiler 92 on the left as viewed in the first direction. The double spoiler 92 protrudes from the side wall part 61 toward the second side in the second direction by the amount H of protrusion. The single spoiler 91 also protrudes from the side wall part 61 toward the second side in the second direction by a predetermined amount of protrusion. The flow path resistance is adjusted by the amount of protrusion by which the spoiler 9 protrudes from the side wall part 61 in the second direction. Increasing the amount of protrusion of the spoiler 9 increases the degree of turbulent flow formation and increases the flow path resistance. Adjusting the amount of protrusion of the spoiler 9 facilitates fine adjustment of the cooling performance.

FIG. 8 is a diagram illustrating an example in which the double spoilers 92 provided in the fin regions RC and RD are viewed in the second direction. Specifically, the fin region RC is provided with the double spoilers 92A to 92C, and the fin region RD is provided with the double spoilers 92D to 92F. The double spoilers 92D to 92F on the downstream side each have an angle θ2 inclined from the first direction, the angle θ2 being set larger than an angle θ1 of each of the double spoilers 92A to 92C on the upstream side, the angle θ1 being inclined from the first direction. That is, the flow path resistance is adjusted by the angle at which the spoiler 9 is inclined from the first direction as viewed in the second direction. Increasing the angle at which the spoiler 9 is inclined increases the degree of turbulent flow formation, and increases the flow path resistance. Adjusting the angle at which the spoiler 9 is inclined facilitates fine adjustment of the cooling performance. The angle at which the single spoiler 91 is inclined may be adjusted.

The embodiment of the present disclosure has been described above. The scope of the present disclosure is not limited to the above embodiment. The present disclosure can be implemented by making various changes to the above embodiment without departing from the gist of the invention. The matters described in the above embodiment can be optionally combined together, as appropriate, as long as there is no inconsistency.

As described above, a heat radiating member according to an aspect of the present disclosure cools an insulating circuit board equipped with a semiconductor element, and includes: a base part in a plate shape that extends in a first direction along a refrigerant flow direction and in a second direction orthogonal to the first direction with a thickness in a third direction orthogonal to the first direction and the second direction, and includes the insulating circuit board disposed on a first side in the third direction; and a plurality of fins that protrudes from the base part toward a second side in the third direction and includes a side wall part in a plate shape extending in the first direction and the third direction and having a thickness direction in the second direction, the plurality of fins being disposed in the second direction, at least one of the plurality of fins including a plurality of fin regions in the first direction, the plurality of fin regions facing a plurality of the semiconductor elements in the third direction, the plurality of the semiconductor elements being disposed in the first direction, and the plurality of fin regions including two or more fin regions each of which includes the side wall part provided with a spoiler, wherein the spoiler is equal in number between the two or more fin regions, and flow path resistance due to structure of the spoiler in each of the fin regions increases from an upstream side toward a downstream side of the corresponding one of the fin regions through which the refrigerant flows (first structure).

The first structure may be configured such that each of sets of the fin regions adjacent to each other in the first direction has the flow path resistance that increases from the fin region on the upstream side toward the fin region on the downstream side (second structure).

The first structure may be also configured such that at least one of the sets of the fin regions adjacent to each other in the first direction has the flow path resistance that is equal between the fin regions adjacent to each other (third structure).

Any one of the first to third structures may be configured such that the flow path resistance is adjusted by a length of the spoiler extending in the first direction and the third direction (fourth structure).

Any one of the first to fourth structures may be configured such that the flow path resistance is adjusted by an amount of protrusion by which the spoiler protrudes from the side wall part in the second direction (fifth structure).

Any one of the first to fifth structures may be configured such that the flow path resistance is adjusted by an angle at which the spoiler is inclined from the first direction as viewed in the second direction (sixth structure).

A semiconductor module according to an aspect of the present disclosure includes the heat radiating member having any one of the first to sixth structures, the insulating circuit board, and the semiconductor element (seventh structure).

A semiconductor module according to an aspect of the present disclosure includes the heat radiating member having any one of the first to seventh structures and the semiconductor element (eighth structure).

The present disclosure can be used for cooling semiconductor elements for various applications.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat radiating member configured to cool an insulating circuit board equipped with a semiconductor element, the heat radiating member comprising:
a base part in a plate shape that extends in a first direction along a refrigerant flow direction and in a second direction orthogonal to the first direction with a thickness in a third direction orthogonal to the first direction and the second direction, and includes the insulating circuit board disposed on a first side in the third direction; and
a plurality of fins that protrudes from the base part toward a second side in the third direction and includes a side wall part in a plate shape extending in the first direction and the third direction and having a thickness direction in the second direction, the plurality of fins being disposed in the second direction,
at least one of the plurality of fins including a plurality of fin regions in the first direction, the plurality of fin regions facing a plurality of the semiconductor elements in the third direction, the plurality of the semiconductor elements being disposed in the first direction, and
the plurality of fin regions including two or more fin regions each of which includes the side wall part provided with a spoiler,
wherein
the spoiler is equal in number between the two or more fin regions, and
flow path resistance due to structure of the spoiler in each of the fin regions increases from an upstream side toward a downstream side of the corresponding one of the fin regions through which the refrigerant flows.

2. The heat radiating member according to claim 1, wherein
each of sets of the fin regions adjacent to each other in the first direction has the flow path resistance that increases from the fin region on the upstream side toward the fin region on the downstream side.

3. The heat radiating member according to claim 1, wherein
at least one of the sets of the fin regions adjacent to each other in the first direction has the flow path resistance that is equal between the fin regions adjacent to each other.

4. The heat radiating member according to claim 1, wherein
the flow path resistance is adjusted by a length of the spoiler extending in the first direction and the third direction.

5. The heat radiating member according to claim 1, wherein
the flow path resistance is adjusted by an amount of protrusion by which the spoiler protrudes from the side wall part in the second direction.

6. The heat radiating member according to claim 1, wherein
the flow path resistance is adjusted by an angle at which the spoiler is inclined from the first direction as viewed in the second direction.

7. A semiconductor module comprising:
the heat radiating member according to claim 1;
the insulating circuit board; and
the semiconductor element.
